(19) United States
(12) Patent Application Publication
(10) Pub. No.: US 2007/0154755 A1
(43) Pub. Date: Jul. 5, 2007

(54) Apparatus for measuring an electrical characteristic of an electrochemical device

(76) Inventor: David S. Wardrop, Vancouver (CA)

Correspondence Address: SEED INTELLECTUAL PROPERTY LAW GROUP PLLC, 701 FIFTH AVE, SUITE 5400, SEATTLE, WA, 98104, US

(21) Appl. No.: 11/322,833

(22) Filed: Dec. 30, 2005

(51) Int. Cl. H01M 8/04; G01R 31/02

(52) U.S. Cl. 429/23; 429/13; 324/537

(57) ABSTRACT

Measurement systems for electrochemical devices employ a semi-conductive measurement strip that can be coupled to the electrochemical device to indicate an electrical characteristic of the electrochemical device. The measurement systems may further include electrical contactors and/or measurement devices. Methods for monitoring cells of an electrochemical device are disclosed for monitoring and analyzing the change over distance of the voltages of the electrochemical device.

### BACKGROUND OF THE INVENTION

1. Field of the Invention

Electrochemical devices convert chemical energy produced by a reaction into electrical energy. Examples of electrochemical devices include batteries and fuel cells. In some cases, electrochemical devices consist of a number of cells connected electrically in series. Electrochemical devices may be used to supply power in a wide variety of applications. Exemplary transportation applications include hybrid electric vehicles (HEV), electric vehicles (EV), Heavy Duty Vehicles (HDV) and Vehicles with 42-volt electrical systems. Exemplary stationary applications include backup power for telecommunications systems, uninterruptible power supplies (UPS), and distributed power generation applications.

2. Description of the Related Art

Electrochemical fuel cells convert reactants, namely a fuel and oxidant, to generate electric power and reaction products. Electrochemical fuel cells generally employ an electrolyte disposed between two electrodes, namely a cathode and an anode.

One type of electrochemical fuel cell is the proton exchange membrane (PEM) fuel cell. PEM fuel cells generally employ a membrane electrode assembly (MEA) comprising a solid polymer electrolyte or ion-exchange membrane disposed between two electrodes.

In a fuel cell, an MEA is typically interposed between two electrically conductive separator or fluid flow field plates that are substantially impermeable to the reactant fluid streams. The separator plates act as current collectors and may provide mechanical support for the MEA. In addition, the separator plates have channels, trenches, or the like formed therein which serve as paths to provide access for the reactant and the oxidant fluid streams to the appropriate electrode layer, namely the anode on the fuel side, and the cathode on the oxidant side. Also, the fluid paths provide for the removal of reaction byproducts and depleted gases formed during operation of the fuel cell.

In a fuel cell stack, a plurality of fuel cells are connected together, typically in series but sometimes in parallel or a combination of series and parallel, to increase the overall output power of the fuel cell system. In such an arrangement, one side of a given separator plate may be referred to as an anode separator plate for one cell and the other side of the plate may be referred to as the cathode separator plate for the adjacent cell.

It can be useful to monitor the performance of sections of the fuel cell stack or of individual cells within the fuel cell stack as an indication of the operating state of the fuel cell stack. For example, once the operating state of the fuel cell stack is known, control actions may be taken to alter or maintain the operating conditions of the fuel cell stack and thus place the fuel cell stack into a desirable state.

The performance of the fuel cells within the fuel cell stacks is typically monitored by measuring the individual differential voltages of the fuel cells.

Voltage measurements may however be made as differential or common mode measurements. Differential voltage measurements indicate the potential difference between defined measurement points. For example differential voltage measurements may indicate the cell to cell voltage, or the potential difference between one group of cells and another group of cells. Common mode measurements are typically made using a single defined referenced. For example, common mode voltage measurements may indicate a cell voltage with respect to an earth potential, or with respect to the fuel cell module frame, vehicle chassis or other suitable reference. Those of ordinary skill in the art will appreciate that either voltage measurement mode may be used to gather useful cell voltage data.

A typical cell voltage monitor (CVM) collects voltage data via suitable electrical connections to the individual cells. Signals representative of the cell voltages are then generated and supplied to a processor which then determines whether a problem condition exists and initiates appropriate action. Since the typical processor cannot accommodate high common mode voltages (i.e., voltages with respect to a common voltage or common ground) and since the voltages encountered in the typical series stack can be quite high (e.g., up to hundreds of volts between cells), the generated signals are usually electrically isolated from the cells themselves via appropriate isolation circuitry. Problems have however been encountered with the electrical connections made to the cells and with the circuitry that generates the electrically isolated signals representative of the cell voltages.

With regards to making electrical connections to the cells, the assembly required is very labor intensive and it is becoming more difficult to align and install contacts as the designs of fuel cells advance and as the separator plates become progressively thinner and more closely spaced. Further, variations in the cell-to-cell spacing (due to manufacturing tolerances and to expansion and contraction during operation of the stack) must be accommodated. Further still, the fuel cell stack may be subject to vibration and thus reliable connections must be able to maintain contact even when subjected to vibration.

The signal generation/electrical isolation circuitry in a CVM is desirably located close to the electrical connections to the cells and hence close to the stack. (This minimizes the high voltage hardware required and the size of the hazardous voltage region in the system. Also the possibility of inadvertently shorting out cells in the stack through the CVM may be reduced.) However, in the immediate vicinity of the stack, the environment may be humid, hot, and either acidic or alkaline. For instance, in solid polymer electrolyte fuel cells, carbon separator plates may be somewhat porous and thus the environment in the immediate vicinity of the plates can be somewhat similar to that inside the cells. Consequently, any metallic hardware in the immediate vicinity of the stack may be subject to corrosion and failure. In particular, conductive traces that separate large voltages (e.g., in printed circuit board based isolation circuitry) are subject to corrosion and bridging via dendrite formation. To prevent this type of failure, such hardware can be appropriately encapsulated or potted to isolate it from the corrosive environment. Still, it is not trivial to provide a satisfactory comprehensive, durable protective coating in this way.

Accordingly, although there have been advances in the field, there remains a need for simple, reliable cell voltage monitors for fuel cell stacks. The present invention addresses these needs and provides further related advantages.

### BRIEF SUMMARY OF THE INVENTION

In one embodiment, a measurement system comprises a semi-conductive measurement strip coupled to an electrochemical device to provide indications of electrical characteristics of the electrochemical device.

In one embodiment, the measurement system comprises a measurement device operable to measure electrical characteristics of the measurement strip that are indicative of electrical characteristics of the electrochemical device.

In one embodiment, a fuel cell system comprises a plurality of fuel cells to provide cell voltages, a semi-conductive measurement strip, and an electrical contactor electrically coupled to the fuel cell stack and to the measurement strip, the electrical contactor operable to provide indications of the voltages of the fuel cells to the measurement strip.

In one embodiment a method to monitor the operation of a fuel cell stack comprises monitoring the change over distance of the voltage of the fuel cell stack, and analyzing the change over distance of the voltage of the fuel cell stack.

In one embodiment a method for monitoring the series connected fuel cells of a fuel cell stack by coupling a semi-conductive measurement strip to the fuel cell stack, and monitoring the change over distance of the voltage of the measurement strip.

In one embodiment a method of operating a fuel cell stack by coupling a semi-conductive measurement strip to the fuel cell stack, monitoring and analyzing the change over distance of the voltage of the measurement strip and taking control actions in response to the analyses of the voltage profile.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn, are not intended to convey any information regarding the actual shape of the particular elements, and have been solely selected for ease of recognition in the drawings.

FIG. 1 is an exploded view illustrating a portion of an electrical measurement system according to one embodiment.

FIG. 2 illustrates an embodiment showing a fuel cell stack electrically connected to a measuring strip via an electrical contactor.

FIG. 3 shows an equivalent electrical model of one embodiment.

FIG. 4 shows an exemplary measurement strip with thickness y, width z, and distance between measurement sample points x.

FIG. 5 is an exploded view of another embodiment of the present invention showing an electrochemical device, three electrical contactors, a measurement strip and a measuring device.

FIG. 6 shows a schematic drawing of an electrical contacting device connected to separator plates in a fuel cell stack.

FIG. 7 is a schematic drawing of another embodiment of the contacting device showing a section of an electrical contacting device connected to separator plates in a portion of a fuel cells stack.

FIG. 8 is an exploded view of another embodiment of the present invention showing a measurement strip coupled to a fuel cell stack.

FIG. 9 shows a bar graph showing an example of the voltages that might exist across each individual cell of a fuel cell stack during operation.

FIG. 10 shows a graph representing the voltages that would be present on a measurement strip coupled to a fuel cell stack having exemplary voltages.

FIG. 11 shows a graph representing differential voltage measurements made along the length of an exemplary measurement strip.

FIG. 12 shows a graph illustrating the presence of any cells below a defined threshold.

FIG. 13 shows a prototype system of one embodiment.

FIG. 14 shows three curves illustrating actual cell voltages.

FIG. 15 shows three curves illustrating predicted measurements of actual cell voltages using an exemplary electrical model and an exemplary measurement strip.

FIG. 16 shows three curves illustrating measured cell voltages using an exemplary prototype system.

FIG. 17 shows three curves illustrating predicted measurements of actual cell voltages using an exemplary electrical model and another exemplary measurement strip.

### DETAILED DESCRIPTION OF THE INVENTION

In the following description and enclosed drawings, certain specific details are set forth in order to provide a thorough understanding of various embodiments of the invention. One skilled in the art will understand, however, that the invention may be practiced without all of these details. In other instances, well-known structures associated with fuel cell systems have not been shown or described in detail to avoid unnecessarily obscuring descriptions of the embodiments of the invention.

Unless the context requires otherwise, throughout the specification and claims which follow, the word “comprise” and variations thereof, such as, “comprises” and “comprising” are to be construed in an open sense, that is as “including, but not limited to.”

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Further more, the particular features, structures, or characteristics may be combined in any suitable manner in one or more embodiments.

The headings provided herein are for convenience only and do not interpret the scope or meaning of the claimed invention.

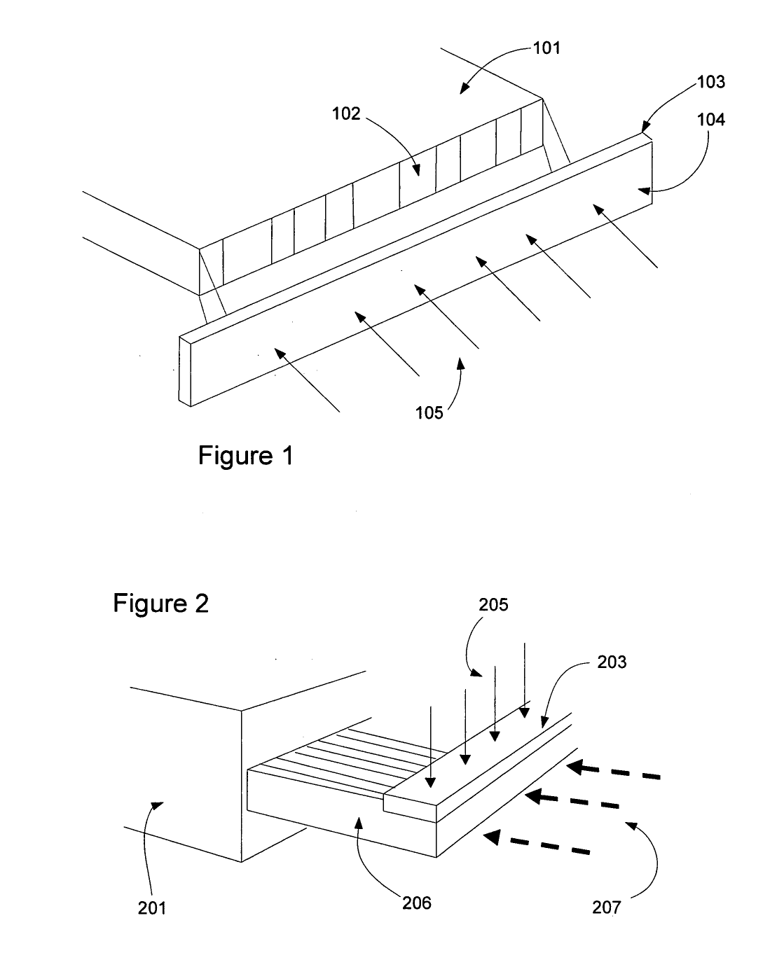

FIG. 1 is an exploded view illustrating a portion of an electrical measurement system according to one embodiment. A fuel cell stack 101 having a plurality of fuel cells 102 is electrically coupled to a measurement strip 103. A plurality of measurement sampling points 105 are disposed on the measurement strip surface 104. A measuring device (not shown) may be electrically coupled to the measurement strip 103 to make a plurality of measurements at measurement sampling points 105. For example, a measuring device such as a digital multimeter (not shown) may be electrically coupled to the measuring strip in order to make a plurality of voltage measurements along the measurement strip surface 104. The voltage measurements made along the measurement strip surface 104 are indicative of the voltages present along the fuel cell stack 101. In other embodiments measurement sensors may be used to make measurements at sampling points 105. These measurement sensors may in turn be coupled to analog-to-digital converters which may provide the resulting digital signals to further processing devices such as microprocessors.

In some embodiments the measurement strip 103 and/or measurement sampling points 105 extend well over the area of the fuel cells to ensure that at least some of the fuel cells are still contacted even if they are shifted by movement or expansion during operation.

The indication of cumulative stack voltage as a function of the physical distance along the direction of fuel cell stacking is called the stack voltage profile. Fuel cell operational status determination may thus be made by taking a series of voltage measurements at spaced points along a stack voltage profile. The stack voltage profile is established on a measurement strip (such as the measurement strip 103 of FIG. 1) electrically connected at various points along its length to an electrochemical device (such as the fuel cell stack 101 of FIG. 1). Monitoring the stack voltage profile may be used as a method to determine the operational state of the electrochemical fuel cell reaction of individual fuel cells or groups of fuel cells and may also be used to determine the electrical interrelations imposed between individual fuel cells.

The measurement strip 103 on which the stack voltage profile is established comprises a semi-conductive material. A highly conductive material would create short circuits between the individual fuel cells or allow current leakage which would detrimentally affect the operation of the fuel cell stack. A totally non-conductive (insulative) material would not convey any indication of the fuel cell stack voltage and thus could not be used to measure the stack voltage profile. For the purpose of being used as a measurement strip, a semi-conductive material is therefore defined as a material that possesses sufficient conductivity to provide an indication of the voltages present on an electrochemical device to which it is coupled, and insufficient conductivity to prohibit the electrochemical device to which it is coupled from fulfilling its intended purpose.

In some embodiments the measurement strip may comprise a material that has sufficient impedance to limit the possible current drawn from the stack to certain levels. For example, it may be desired that the impedance of the measurement strip is such that the total current that may pass through the strip is below a safety threshold. Such a measurement strip would therefore provide improved electrical safety.

The measurement strip may comprise a continuous surface, and therefore may place no physical restrictions on exactly where the fuel cell stack (or an intermediate electrical contactor) should contact the measurement surface, and no physical restrictions on where the measurements of the stack voltage profile should be made along the length of the measurement strip. Furthermore, should any individual cell fail to electrically contact the measurement strip (either directly or through an intermediate electrical contactor), a good approximation to the missed cell's contribution to the stack voltage profile is inherently generated by contact of any other nearby cells.

The measurements made along the length of the measurement strip may be differential or single ended voltage measurements, and may be made at equally spaced or variably spaced physical distances. For example, in some embodiments voltage measurements may be made at equally spaced physical distances at some multiple of the cell pitch. Cell pitch is defined as the cell-to-cell spacing within the electrochemical device. In other embodiments variable spacing distances may be used between voltage measurements. For example, measurements may be taken with narrow spacing near the fuel cell stack ends, and at wider spacing in the middle of the fuel cell stack.

In another embodiment it may be desirable to fabricate one measurement device that provides a series of equally spaced differential voltage measurements. This device could then be used with any fuel cell stack to monitor the stack voltage profile, regardless of cell pitch. In some embodiments this device may be modular, such that a plurality of these devices could be arranged in series to monitor the stack voltage profile of a fuel cell stack of any size.

FIG. 2 illustrates an embodiment showing a fuel cell stack 201 electrically connected to a measuring strip 203 via an electrical contactor 206. Electrical measurements may be made at measurement sampling points 205. A plurality of measurements may be made at the measurement sampling points 205 by a measuring device (not shown). Pressure may be exerted on the electrical contactor 206 in the direction shown by the dotted arrows 207 in order to maximize physical contact between the electrical contactor 206 and the fuel cell stack 201, in order to enhance electrical contact between these two devices.

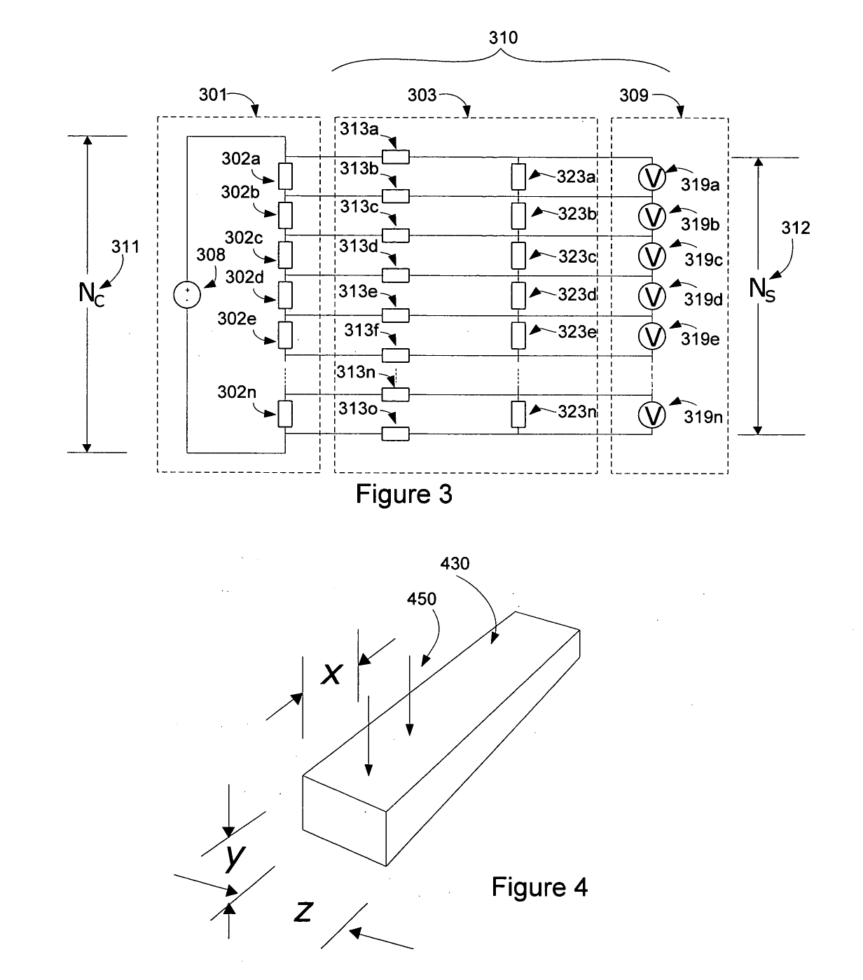

FIG. 3 shows an equivalent electrical model of one embodiment. In the illustrated model the fuel cell stack 301 is modeled as a voltage source 308 electrically connected in series to a plurality of fuel cell model resistors 302a-302n, wherein each resistor models an individual fuel cell 302. To model a weak or underperforming fuel cell, the corresponding fuel cell model resistor 302a-302n could have a lower resistance than the other fuel cell model resistors. For example, in order to model a fuel cell stack wherein all the fuel cells are operating at the same fuel cell voltage V, except for one fuel cell which is operating at half that voltage (0.5*V), each of the fuel cells operating at the voltage V could be modeled by a fuel cell model resistor 302a-302n having a 1 Ohm resistance, and the fuel cell operating at (0.5*V) could be modeled by a fuel cell model resistor 302a-302n having a resistance of 0.5 Ohms.

The measurement strip 303 is modeled by two types of resistances. Electrical resistance present in the path between the fuel cells 302 and the point of measurements on the measurement strip 303 are modeled as series resistances R_{S} 313a-313o. Resistances R_{S} 313a-313o may represent the resistance of the measurement strip 303 in a plane substantially perpendicular to the measurement strip surface, as well as the contact resistances and series resistances of the electrical contactor (not shown). In the illustrated model, resistances R_{S} 313a-313o are most heavily influenced by the resistivity of the measurement strip material in the relevant plane, and by the thickness of the material in this plane.

Electrical resistance present in the path between the measurement sampling points on the measurement strip 303 are modeled as series resistances R_{L} 323a-323n. In the illustrated model the resistances R_{L} 323a-323n are most heavily influenced by the resistivity of the measurement strip material in the relevant plane, and the distances between the measurements taken in this plane.

In some embodiments the measuring strip 303 may be substantially electrically isotropic with respect to conductivity, i.e., the electrical conductivity characteristics of the material are approximately equal in all directions of the material. In a model of an electrical conductivity isotropic material, all resistances R_{L} 323a-323n would be substantially equal to each other if the distances between measurements are equal, and all resistances R_{S} 313a-313o would be substantially equal to each other if the material had uniform thickness in the plane corresponding to the resistances R_{S} 313a . . . 313o. In one embodiment each of the resistances R_{L} 323a-323n could have a resistance of for example approximately 5 kOhms and each of the resistances R_{S} 313a-313o may have a resistance of for example approximately 1.4 kOhms.

In some embodiments the measurement strip may comprise an electrically anisotropic material with respect to conductivity. In this case, the resistances R_{L} 323a-323n may not be equal to one another if the distances between measurements are equal, and the resistances R_{S} 313a-313o may not be equal to one another even if the measurement strip has a uniform thickness.

In some embodiments the measurement strip may comprise a material which has a substantially constant conductivity along one axis, and a substantially constant but different conductivity along one or more of its other axes. In some embodiments the measurement strip may comprise a substantially homogenous material. In some embodiments the measurement strip may be formed of two or more materials or a non-homogenous material.

In some embodiments the measurement strip may further be shaped to exhibit the desired electrical resistance characteristics. For example, an electrically isotropic material with respect to electrical conductivity may be shaped to have a smaller cross sectional area in sections where higher resistance is desired. Thus shaping of a measurement strip material that has a substantially constant electrical conductivity may have the same effect as using a material that displays a variable electrical conductivity. Variable electrical conductivity (or electrical resistance) may be desired to enhance the capability of the measurement strip to draw a small load from the fuel cell stack thus reducing the voltage of the fuel cell stack when a primary load is not connected to the fuel cell stack. Variable electrical conductivity (or electrical resistance) may further be desired in order to enhance the sensitivity of the measurements at chosen areas of the measurement, for example near the ends of the fuel cell stack.

A measuring device 309 is modeled by a plurality of voltage sensors 319a-319n. In the figure, the number of fuel cells 302 in the fuel cell stack 301 is shown as N_{C} 311. The number of measurement samples made over the length of the measurement strip 303 is equal to the number of voltage sensors 319a-319n, and is represented by N_{S} 312. In some embodiments the number of measurement samples N_{S} 312 is equal to the number of fuel cells N_{C} 311. The number of measurement samples N_{S} 312 may be greater than, equal to, or less than the number of fuel cells N_{C} 311. The ratio of the number of cells N_{C} 311 to the number of measurement samples N_{S} 312, may affect the resolution of the stack voltage profile, and may be chosen according to the desired application.

The model illustrated in FIG. 3 may be used as a tool to determine some of the characteristics required in a material for use as the measurement strip. The model may also be used to consider other characteristics of the measurement apparatus 310 that might be of interest. For example, the model may be used to determine a desired characteristic of the voltage sensors 319a-319n such as sensitivity or resolution. As another example the model may also be used to determine characteristics such as the cell to cell electrical isolation of the measurement apparatus 310.

In the exemplary model above, the ratio of resistances R_{S} (313a-313o) to resistances R_{L} (323a-323n) is approximately 1.4 kOhms to approximately 5 kOhms, or stated another way, R_{S}:R_{L} is approximately 1:3.6. Other ratios of R_{S}:R_{L} may be desirable. For example, a desired measurement strip material may have a R_{S}:R_{L} ratio of approximately 1:20.

In some embodiments a suitable material for the measurement strip may be chosen as follows:

Considering a homogenous (electrically isotropic) material with a resistivity p, the following equation applies:

$$R = L * \frac{ρ}{A} \qquad ( equation 1 )$$

Where:

R=resistance in Ohms (Ω)

L=length in meters (m)

ρ=resistivity in Ohms per meter (Ω/m)

A=cross sectional area in meters squared (m²)

Referring to FIG. 4, an exemplary measurement strip 403 is shown with thickness y, width z, and distance between measurement sample points x. Relating the measurement strip 403 of FIG. 4 to the model of the measurement strip 303 in FIG. 3, R_{S} is the material resistance in a plane corresponding to the width z of the measurement strip. Similarly R_{L} is the material resistance for the path along the measurement distance x, between measuring sample points 405.

Therefore, using equation 1:

$$\begin{matrix}{R}_{S} = \frac{ρ * z}{x * y} \\ And & ( equation 2 ) \\ {R}_{L} = \frac{ρ * x}{y * z} & ( equation 3 )\end{matrix}$$

Using the model shown in FIG. 3 above, a material exhibiting the property wherein R_{S}:R_{L} is greater than approximately 1:20 is chosen:
20*R_{S}<R_{L} (equation 4)

Substituting equation 2 and equation 3 into equation 4 above results in the following equation:

$$\frac{20 * ( ρ * z )}{x * y} < \frac{( ρ * x )}{y * z} \qquad ( equation 5 )$$

Solving equation 5 yields:
4.47*z<x (equation 6)
x is then chosen to provide the desired measurement distance. This may be related to the cell pitch. For example, in a fuel cell stack where the cell pitch is 2 mm and the number of measurements is desired to be equal to the number of cells, the measurement distance x may be chosen to also be 2 mm. As discussed above, the number of measurements does not need to equal the number of cells in the fuel cell stack. For example the cell pitch could be 2.2 mm, and the measurement distance could be 2 mm. This would correspond to making 220 measurements on a fuel cell stack of 200 cells.

Choosing a measurement distance of x=2 mm, and solving equation 6 results in a required measurement strip width z<0.45 mm.

Further, assuming a measurement strip material of thickness y=5 mm, the above calculated values for x and z, and solving equation 5, yields ρ>2250 Ωcm. Therefore for the R_{S}:R_{L} ratio, material thickness, and measuring distance chosen above, the homogenous measuring strip material should have a resistivity greater than approximately 2250 Ωcm. This may correspond to, for example, a polycarbonate material.

The thickness y may be chosen to suit the application or may be a limitation imposed by the commercial availability of the chosen material.

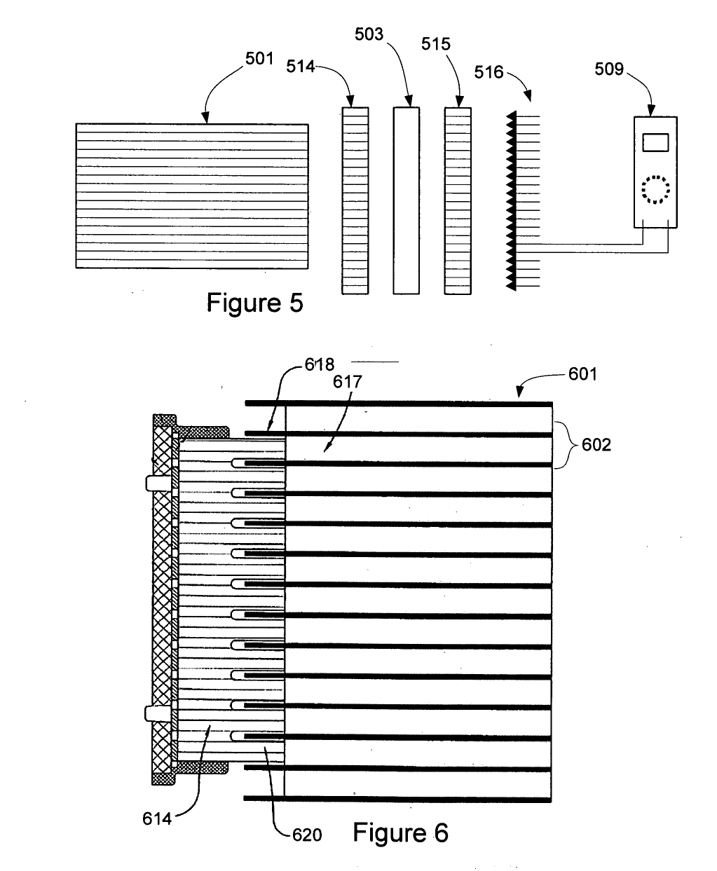

FIG. 5 is an exploded view of another embodiment of the present invention. Electrochemical device 501 with cells 502 is electrically coupled to the measurement strip 503 via a first electrical contactor 514. In some embodiments the first electrical contactor 514 may comprise an elastomeric contactor. An example of a suitable elastomeric contactor is a Zebra® elastomeric connector available from Fujipoly America Corporation. Examples of other suitable contactors are disclosed in US patent application publication US2003/0215678. The electrical contactor may however comprise any contactor suitable to electrically couple the electrochemical device 501 to the measurement strip 503.

In the illustrated embodiment a second electrical contactor 515 is electrically coupled between the measurement strip 503 and components of a measuring device 509. In some embodiments the second electrical contactor 515 may comprise an elastomeric contactor.

A third electrical contactor 516 is electrically coupled between the second electrical contactor 515 and the measurement device 509. The third electrical contactor 516 may for example comprise a readily available 2.51 mm Pin Connector. One skilled in the art will recognize that many other electrical contactors would be suitable for this application. Other embodiments may utilize all, some or none of the electrical contactors 514, 515, 516. A measuring device 509 is electrically coupled to the third electrical contactor 516, and operable to measure electrical characteristics of the measurement strip 503. The measurement device 509 may measure any electrical characteristic, for example voltage. The measurement device 509 may measure the voltage across some or all of the contacts of the third electrical contactor 516. The measurement device 509 may be a relatively simple device such as a voltmeter, multimeter, or digital multimeter, or it may be a more complex measurement device such as a measurement system comprising signal conditioning, multiplexing, analog to digital conversion, signal processing, data storage, and data communication.

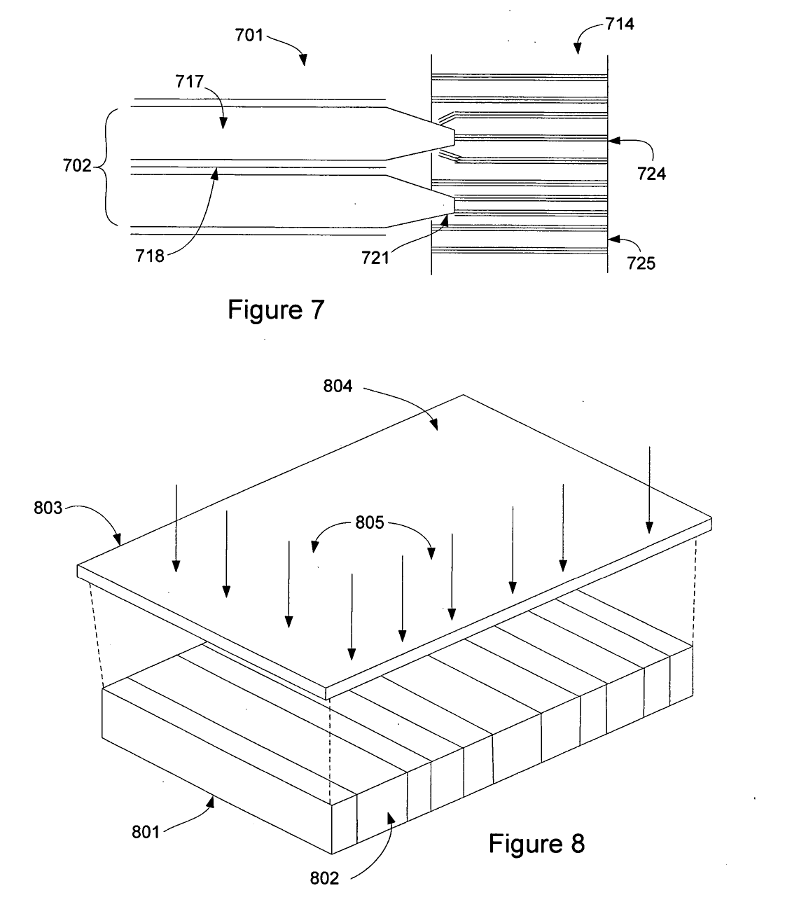

FIG. 6 shows a schematic drawing of an electrical contacting device 614 connected to separator plates 617 in a fuel cell stack 601. Fuel cell stack 601 contains a series stack of fuel cells 602 each of which comprise a membrane electrode assembly (MEA) 618 sandwiched between two separator plates 617. As shown in FIG. 6, the membrane electrolyte in membrane electrode assembly 618 extends beyond the edge of separator plates 617 and into the slots separating contacts 620, thereby preventing electrical shorting between adjacent contacts 620. Various alignment, compression, and retaining devices may be used to couple the electrical contacting device 614 to the fuel cell stack 601.

FIG. 7 is a schematic drawing of an embodiment of an electrical contacting device showing a section of an electrical contacting device 714 connected to separator plates 717 in a portion of a fuel cells stack 701. Fuel cell stack 701 contains a series stack of fuel cells 702 each of which comprise a membrane electrode assembly (MEA) 718 sandwiched between two separator plates 717. As shown in FIG. 7, the separator plates 717 extend beyond the edge of the membrane electrode assemblies (MEAs) 718. In this embodiment the edges of the separator plates 717 are angled away from each neighboring separator plate 717 to form respective points 721. In this embodiment the separator plates 717 are pointed to ensure that a single conductive portion 724 of the electrical contacting device 714 cannot cause a short circuit between two adjacent separator plates 717 by simultaneously contacting both separator plates 717. Conductive portions 724 of the electrical contacting device 714 are separated by non-conductive portions 725.

In some embodiments, for example where either or both of the dimensions of the MEA 718 and of the conductive portions 724 are such that it is impossible for a single conductive portion 724 to contact two separator plates 717 simultaneously, the tips of the separator plates do not need to be angled away from one another, and may be of any suitable shape. As in FIG. 6 above, various alignment, compression, and retaining devices (not shown) may be used to couple the electrical contacting device 714 to the fuel cell stack 701.

FIG. 8 is an exploded view illustrating another embodiment of the invention. In this illustrated embodiment the measurement strip 803 is coupled to the fuel cell stack 801 along the top surface of the fuel cell stack 801. As in FIG. 1, the fuel cell stack 801 comprises a plurality of fuel cells 802. As further shown in this embodiment, measurements may be made anywhere along the measurement strip surface 804, for example at measurement sampling points 805. The illustrated embodiment can therefore be used to monitor the voltage distribution along a single cell 802 of the fuel cell stack 801, a stack voltage profile along the direction of stacking of the fuel cell stack, or to create a two-dimensional matrix representing both these measurements. Similarly, it will be appreciated that in other embodiments the measurement strip may be coupled along any other suitable surface of the fuel cell stack to monitor an electrical characteristic of the fuel cell stack. In other embodiments multiple measurement strips may be used, or a measurement strip may be shaped to contact multiple surfaces of the fuel cell stack. These embodiments may enable spatial, three-dimensional, representation of the measured electrical characteristic of the fuel cell stack.

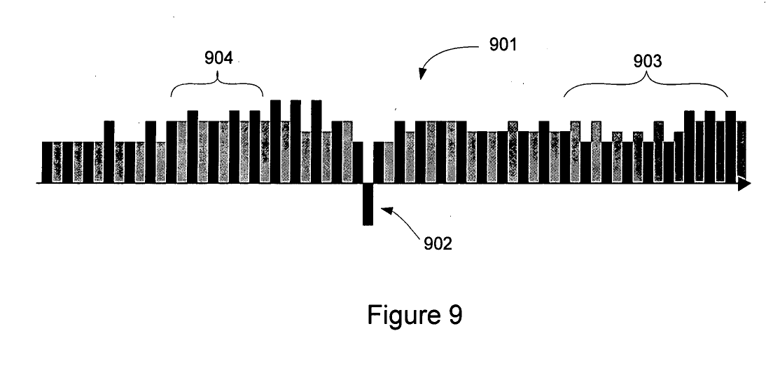

FIG. 9 depicts a bar graph 901 showing an example of the voltages that might exist across each individual cell of a fuel cell stack during operation. It is possible for an underperforming cell to reach negative voltages during operation, such as shown at 902. This phenomenon is known as cell reversal. Cell reversal is generally not a desirable operating condition during normal operation of a fuel cell stack. Cell reversal can represent a fuel cell consuming power instead of producing power and may lead to effects such as local heating which may damage the fuel cell and lead to other adverse effects on the fuel cell stack. Traditional uses for cell voltage measurements include sensing the presence of cells that have gone into reversal or that are below a certain voltage threshold, and identifying these cells; thus enabling a control system to perform certain control actions to correct the situation.

Various other information gained from cell voltage measurements may also be used to determine control actions or to analyze the operation of the fuel cell system. For example, various features present in the cell voltage measurements such as the ragged measurements shown at 903 or the substantially smooth measurements shown at 904 could be indicative of certain desired or undesired states within the fuel cell system, and control actions could be made to either alter undesired states, or to maintain desired states. For example, the ragged measurements at 903 could be indicative of an insufficient oxidant flow through the fuel cells, and the control action taken to modify this operational state could comprise sending a signal to a blower (not shown) to increase oxidant flow through the fuel cells.

The analyses of the fuel cell voltages may further comprise monitoring other operational parameters of the fuel cell system, and combining information gained from the monitoring of those parameters with the information gained from the monitoring of the fuel cell voltages. Examples of other parameters that may be monitored within the fuel cell system include pressures, flows, electrical loads, temperatures, relative humidities, user inputs, and ambient conditions, among others.

Various control actions may be taken in response to analyses of the fuel cell voltages and other operational parameters of the fuel cell system. The actions taken may include, but are not limited to, increasing or decreasing the flow rates of the supplied fuel, oxidant, and/or coolant, increasing or decreasing the pressures of the supplied fuel, oxidant, and/or coolant, increasing or decreasing the relative humidity of the supplied fuel and/or oxidant, increasing or decreasing the temperatures of the supplied fuel, oxidant, and/or coolant, and purging the cathode and/or anode of the fuel cell stack.

The control actions may further comprise limiting the amount of power produced by the fuel cell system, and/or limiting the rate at which this power is produced. This may be used for example to provide a “limp home” capability to a fuel cell system. The control action may also include alerting the user of the fuel cell system. It can be appreciated that any number and type of control actions may be taken in response to analyses of the fuel cell voltages.

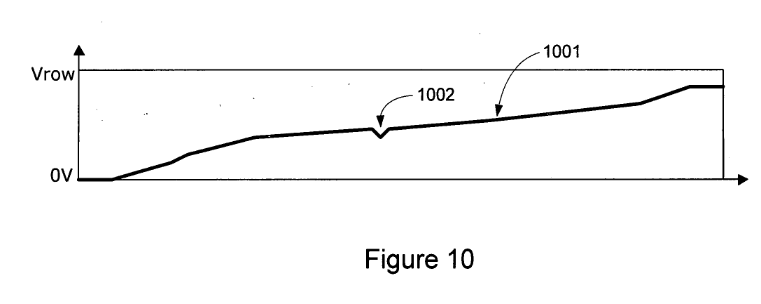

FIG. 10 shows a graph 1001 representing the voltages that would be present along a measurement strip coupled to a fuel cell stack having the exemplary voltages shown in FIG. 9. Single ended voltage measurements taken across the length of the measurement strip such as shown in the FIGS. 1-9 would result in a graph similar to the one shown in FIG. 10. As can be seen, the voltage across the measurement strip rises from 0 volts (with respect to one end of the fuel cell stack) to the total voltage produced by the fuel cell stack. As can also be seen from FIG. 10, features of the cell voltages may also be identified on this graph, for example, the low voltage at 902 in FIG. 9 may be seen indicated at 1002 on FIG. 10.

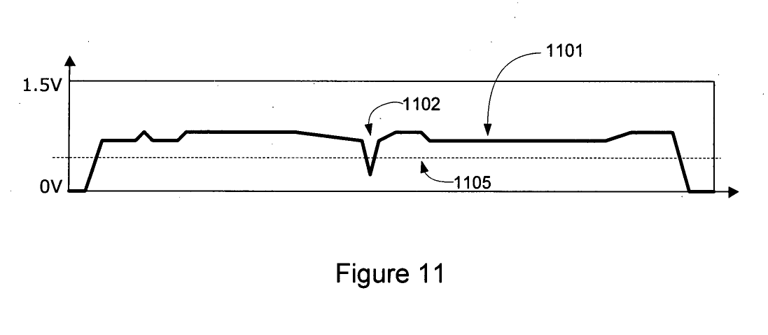

FIG. 11 shows a graph 1101 representing differential voltage measurements made along the length of the exemplary measurement strip of FIG. 10. It should be appreciated that this graph may also be derived from single ended measurements made along the length of the measurement strip. Representing the measured cell voltages in this format highlights some of the features of the voltage measurements discussed in FIG. 9 above. For example the low cell voltage shown at 902 in FIG. 9 is clearly identifiable as feature 1102 in FIG. 11. Further analyses of the curve 1101 may be made to identify suitable control actions for the fuel cell system as described above. For example, threshold 1105 may be used to identify the presence of cells below a certain voltage.

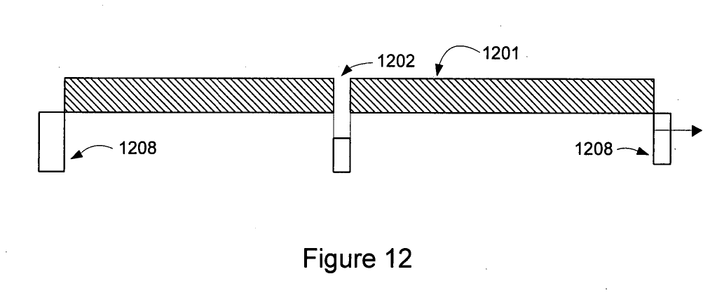

FIG. 12 shows a graph 1201 illustrating the presence of any cells below a threshold 1105 defined in FIG. 11. The graph 1201 may further identify the edges of the fuel cell stack at 1208 to ensure that these are differentiated from any cells below the threshold 1105. The feature at 1202 identifies the event comprising a cell voltage below a threshold voltage corresponding to the low cell voltage shown at 902, 1002, and 1102 in FIGS. 9-11 respectively.

Algorithms other than the simple threshold comparison shown above may be used to determine the operating state of the fuel cell stack. For example, the curves 1001 and 1101 shown in FIGS. 10 and 11 may be analyzed using threshold detection techniques, peak detection techniques, slope detection techniques, edge detection techniques or techniques utilizing frequency domain analysis methods and/or statistical methods, among others.

It will be understood by those skilled in the art that the collection and analyses of the voltage measurements can be performed individually and/or collectively, by a wide range of hardware, software, firmware, or virtually any combination thereof.

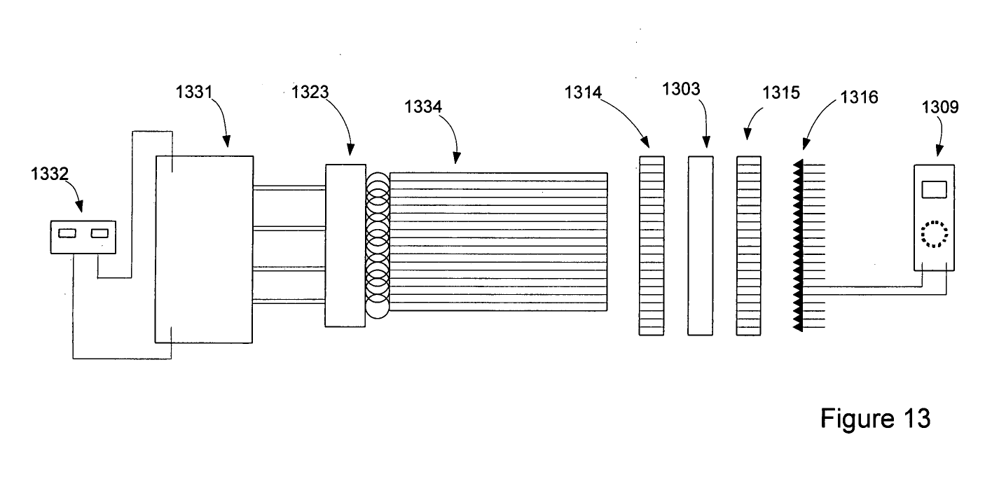

FIG. 13 shows a prototype system of one embodiment. Stack simulator 1331 converts a single DC voltage received from the DC power supply 1332, to a plurality of DC voltages of different magnitudes, and makes these available via a connection board with pickup hoops 1323. An isolated plate 1334 with alternating conducting and non-conducting regions is electrically connected to the pickup hoops 1323, thus conducting along its length a plurality of DC voltages and thus simulating a fuel cell stack. A first electrical contactor 1314 is electrically coupled between the isolated plate 1334, and a measurement strip 1303. The first electrical contactor 1314 thus provides indications of the voltages present on the isolated plate 1334 to the measurement strip 1303. The measurement strip 1303 is constructed from a polycarbonate material. A second electrical contactor 1315 is coupled to the measurement strip 1303 in order to simplify the electrical connection of a measurement device 1309 to the measurement strip 1303. Both the first electrical contactor 1314 and second electrical contactor 1315 are elastomeric electrical contactors. A third electrical contactor 1316 is electrically coupled to the second electrical contactor 1315. The third electrical contactor 1316 is a 2.51 mm pin connector. This type of connector makes it simple to connect to the measurement strip 1303 via the second electrical contactor 1315, as the metallic pins of the third electrical contactor 1316 may simply be pressed into the elastomeric material of the second electrical contactor 1315 in order to create a suitable electrical contact. This eliminates the need for soldering or other methods of ensuring electrical connection. A measuring device 1309, in this case a digital multimeter, is then used to measure voltages on the third electrical contactor 1316. One skilled in the art will appreciate that any manner or number of electrical contactors may be used to achieve the same results. In the illustrated prototype the cell pitch of the isolated plate 1334 is 2.2 mm and the distance between measurements on the measurement strip 1303 is 2.51 mm (governed by the distance between each contact of the third electrical contactor 1316).

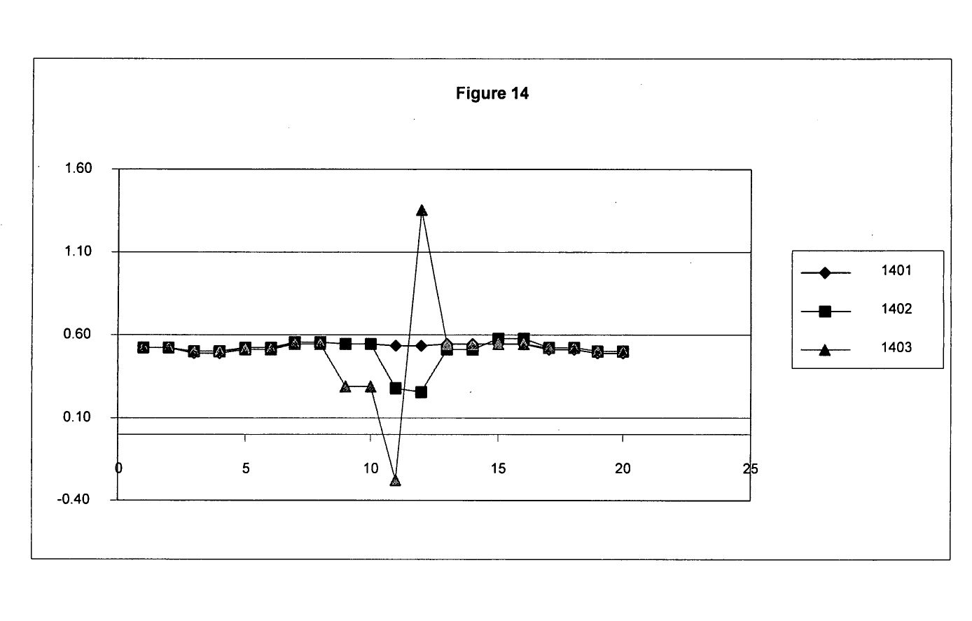

FIGS. 14-17 illustrate actual, predicted, and measured cell voltages. FIG. 14 displays 3 curves 1401, 1402, and 1403, illustrating actual cell voltages that were used to demonstrate the applicability of the model shown in FIG. 3, and to gauge the accuracy of the model by measuring the actual voltages using the prototype system shown in FIG. 13. Twenty individual cell voltages ranging from approximately −0.4V to approximately 1.5V were used.

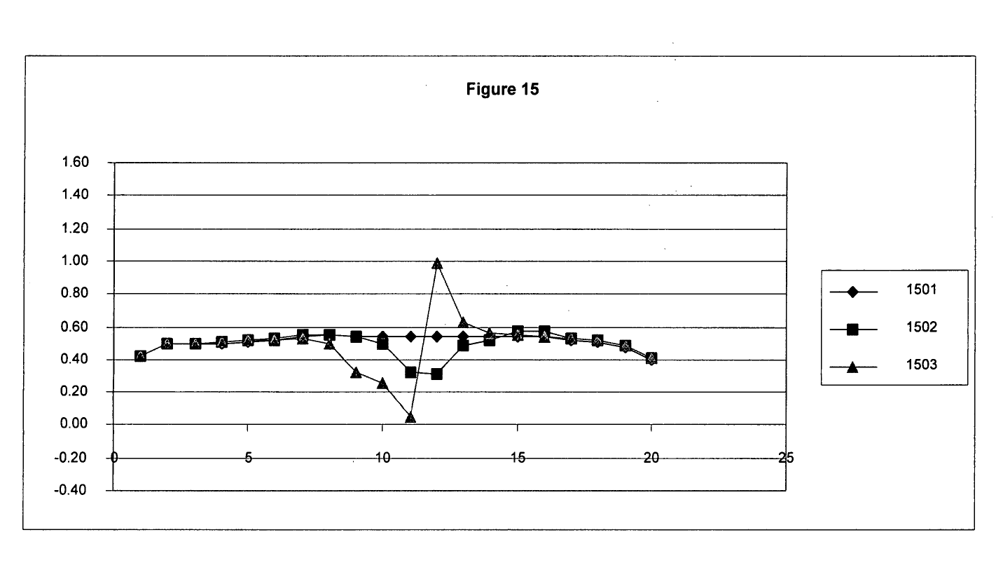

FIG. 15 shows the resulting measurement curves 1501, 1502, and 1503 predicted by the model illustrated in FIG. 3, using the cell voltage curves shown at 1401, 1402, and 1403 respectively.

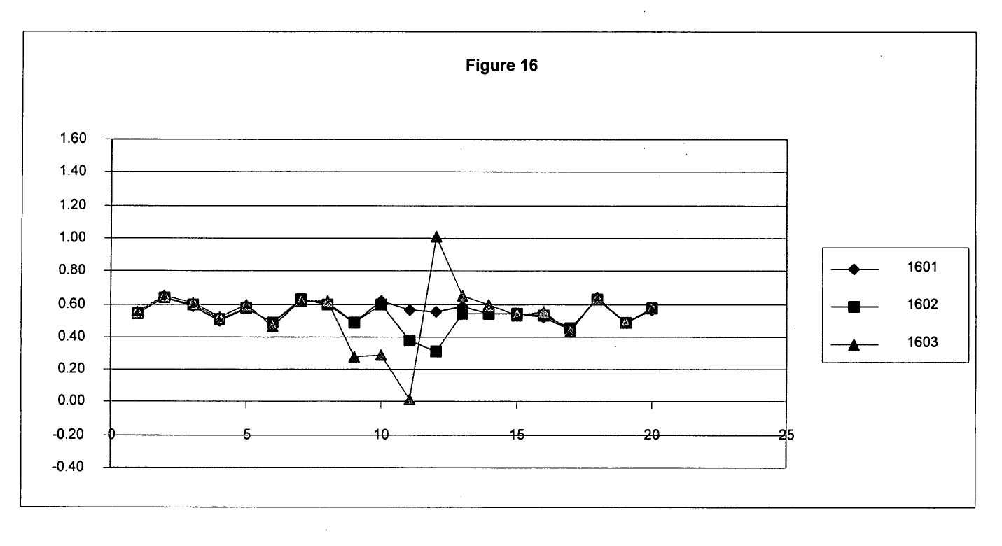

FIG. 16 shows actual measurement curves 1601, 1602, and 1603, measured using the prototype system shown in FIG. 13, using cell voltages as shown at 1401, 1402, and 1403 respectively. As can be seen from FIGS. 14-16, close correlations between the actual, predicted, and measured cell voltages exist.

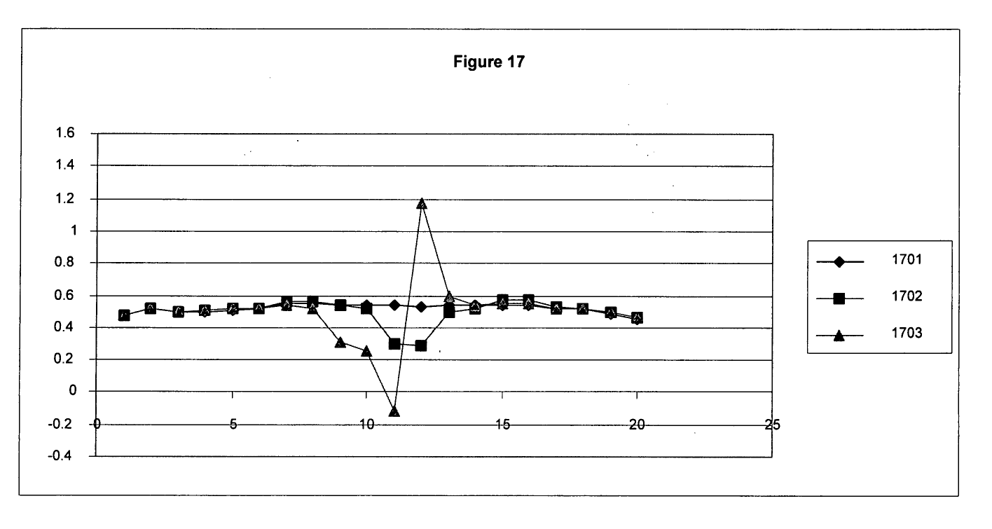

FIG. 17 shows three measurement curves 1701, 1702, and 1703 predicted by the model illustrated in FIG. 3, using the cell voltage curves shown at 1401, 1402, and 1403 respectively, and using a material different from the material used in the calculations for FIG. 15 for the measurement strip.

The foregoing detailed description has set forth various embodiments of the devices and/or processes via the use of block diagrams, schematics, and examples. Insofar as such block diagrams, schematics, and examples contain one or more functions and/or operations, it will be understood by those skilled in the art that each function and/or operation within such block diagrams, flowcharts, or examples can be implemented, individually and/or collectively, by a wide range of hardware, software, firmware, or virtually any combination thereof. In one embodiment, parts of the present subject matter may be implemented via Application Specific Integrated Circuits (ASICs). However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure. In some embodiments, measurement, analysis, and control may be coordinated among various subsystems such as for example a measurement instrument, a measurement controller and a fuel cell system controller. In some embodiments this coordination may be achieved using digital communications, for example via a Controller Area Network (CAN).

In addition, those skilled in the art will appreciate that the measurement, analyses, and control mechanisms taught herein are capable of being distributed as a program product in a variety of forms, and that an illustrative embodiment applies equally regardless of the particular type of signal bearing media used to actually carry out the distribution. Examples of signal bearing media include, but are not limited to, the following: recordable type media such as floppy disks, hard disk drives, CD ROMs, digital tape, and computer memory; and transmission type media such as digital and analog communication links using TDM or IP based communication links (e.g., packet links).

Although specific embodiments of and examples for the measuring system and methods are described herein for illustrative purposes, various equivalent modifications can be made without departing from the spirit and scope of the disclosure, as will be recognized by those skilled in the relevant art. The teachings provided herein can be applied to other measurement systems, not necessarily the electrochemical device measurement system generally described above.

Portions of the measurement system may be integrated into a housing to form a measurement module (not shown). For example, an electrical contactor may be coupled with a measurement strip to form a measurement module that may be easily couple to any electrochemical device. The measurement module may further comprise sensors coupled between the measurement strip and a measurement controller.

Portions of the measurement system may further be integrated into a housing forming a fuel cell module. For example, a measurement strip may be coupled to a fuel cell stack within a fuel cell module, thus providing a measurement surface to which a measuring device may be coupled. In some embodiments, the measuring device (and any associated electrical connections) may also be integrated into the fuel cell module.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet, are incorporated herein by reference, in their entirety. Aspects of the invention can be modified, if necessary, to employ systems, circuits and concepts of the various patents, applications and publications to provide yet further embodiments of the invention.

These and other changes can be made to the invention in light of the above-detailed description. In general, in the following claims, the terms used should not be construed to limit the invention to the specific embodiments disclosed in the specification and the claims, but should be construed to include all measurement systems. Accordingly, the invention is not limited by the disclosure, but instead its scope is to be determined entirely by the following claims.

1. An apparatus for indicating an electrical characteristic of a plurality of cells of a multi-cell electrochemical device comprising:
a semi-conductive measurement strip electrically coupleable to at least a portion of the multi-cell electrochemical device, whereby during operation the measurement strip exhibits an electrical characteristic indicative of the electrical characteristic of the portion of the multi-cell electrochemical device.

2. The apparatus of claim 1 wherein the electrochemical device is a fuel cell stack.

3. The apparatus of claim 1 wherein the indicated electrical characteristic of the portion of the electrochemical device is the voltage of the cells of the electrochemical device.

4. The apparatus of claim 1 wherein the electrical characteristic exhibited by the measurement strip is a voltage indicative of the electrical characteristic of the plurality of cells of the multi-cell electrochemical device.

5. The apparatus of claim 1 wherein the measurement strip comprises a substantially isotropic material with respect to electrical conductivity.

6. The apparatus of claim 1 wherein the measurement strip comprises a polycarbonate material.

7. The apparatus of claim 1 wherein the measurement strip comprises a substantially anisotropic material with respect to electrical conductivity.

8. The apparatus of claim 1, further comprising:
a measuring device electrically coupleable to the measurement strip and operable to measure the electrical characteristic of the measurement strip indicative of the electrical characteristic of the plurality of cells of the multi-cell electrochemical device.

9. The apparatus of claim 8 wherein the measuring device is further operable to make a plurality of measurements at points along the measurement strip.

10. The apparatus of claim 9 wherein the plurality of measurements are made at fixed distances along the length of the measuring strip in a direction corresponding to the direction of stacking of the plurality of cells in the electrochemical device.

11. The apparatus of claim 9 wherein the plurality of measurements are made at variable distances along the length of the measuring strip in a direction corresponding to the direction of stacking of the plurality of cells in the electrochemical device.

12. The apparatus of claim 9 wherein the measuring device is operable to make a plurality of voltage measurements at points along the measurement strip.

13. The apparatus of claim 9, further comprising:
a first point of contact between the measurement strip and a cell of the multi-cellular electrochemical device;
a second point of contact between the measurement strip and a first point of measurement of the measuring device;
a third point of contact between the measurement strip and a second point of measurement of the measuring device; wherein
the measurement strip has an electrical resistance RL between the first point of contact and the second point of contact, and an electrical resistance RS between the second point of contact and the third point of contact; and wherein
the measurement strip comprises a material possessing the property wherein the ratio of RS:RL is greater than approximately 20:1.

14. The apparatus of claim 9, further comprising means for analyzing the plurality of measurements of the electrical characteristics of the measurement strip.

15. The apparatus of claim 14 wherein the means for analyzing the plurality of measurements of the electrical characteristics of the measurement strip comprises a controller operable to analyze the plurality of measurements of the electrical characteristics of the measurement strip.

16. The apparatus of claim 14, further comprising means for causing a control action to be performed in response to the analysis of the plurality of measurements.

17. The apparatus of claim 16 wherein the control action comprises a control action selected from the list of shutting down the fuel cell system, placing the fuel cell system in a reduced power operating state, alerting the operator of the fuel cell system, and modifying the operating conditions of the fuel cell system, or any combination thereof.

18. The apparatus of claim 16 wherein the means for causing a control action to be performed comprises a controller operable to cause a control action to be performed.

19. A fuel cell system, comprising:
a plurality of fuel cells, the fuel cells electrically connected to form a fuel cell stack;
a semi-conducting measurement strip; and
an electrical contacting device electrically coupleable between at least one of the plurality of fuel cells and the measurement strip, wherein the contacting device is operable to provide indications of a voltage of the at least one cell to the measurement strip.

20. The system of claim 19 wherein the electrical contacting device comprises a plurality of electrical contacts, each electrically insulated from the other.

21. The system of claim 20 wherein the plurality of electrical contacts comprise a non-metallic, electrically conductive elastomer composition.

22. The system of claim 21 wherein the elastomer composition comprises an elastomer and a non-metallic electrical conductor.

23. The system of claim 20 wherein the electrical contacting device and comprises alternating electrically conductive elastomer composition layers and electrically non-conductive elastomer layers.

24. The system of claim 19 wherein the measurement strip comprises a substantially isotropic material with respect to electrical conductivity.

25. The system of claim 19 wherein the measurement strip comprises a polycarbonate material.

26. The system of claim 19 wherein the measurement strip comprises a substantially anisotropic material with respect to electrical conductivity.

27. The system of claim 19, further comprising:
a measuring device electrically coupleable to the measurement strip and operable to measure at least one measurement strip voltage indicative of at least one cell voltage of the fuel cell stack.

28. The system of claim 27 wherein the measuring device is further operable to measure a plurality of measurement strip voltages.

29. The system of claim 28 wherein the plurality of measurement strip voltage measurements are made at fixed distances along the length of the measuring strip in a direction corresponding to the direction of stacking of the plurality of cells in the fuel cell stack.

30. The system of claim 28 wherein the plurality of measurement strip voltage measurements are made at variable distances along the length of the measuring strip in a direction corresponding to the direction of stacking of the plurality of cells in the electrochemical device.

31. The system of claim 28, further comprising:
a first point of contact between the measurement strip and the electrical contacting device;
a second point of contact between the measurement strip and a first point of measurement of the measuring device;
a third point of contact between the measurement strip and a second point of measurement of the measuring device; wherein
the measurement strip has an electrical resistance RL between the first point of contact and the second point of contact, and an electrical resistance RS between the second point of contact and the third point of contact; and wherein
the measurement strip comprises a material possessing the property wherein the ratio of RS:RL is greater than approximately 20:1.

32. A method for monitoring series connected fuel cells of a fuel cell stack, comprising:
monitoring a stack voltage profile; and
analyzing the stack voltage profile to determine if any of the fuel cells in the fuel cell stack fall below a threshold voltage.

33. A method for monitoring fuel cells of a fuel cell stack, comprising:
electrically coupling a semi-conductive measurement strip to at least one of the fuel cells of the fuel cell stack; and
monitoring a change over distance of the voltages present on the measurement strip.

34. The method of claim 33, further comprising analyzing the change over distance of the voltages to determine the operating state of the fuel cell stack.

35. The method of claim 33 wherein monitoring a change over distance of the voltage present on the measurement strip comprises making a plurality of voltage measurements on the measurement strip.

36. The method of claim 34 wherein analyzing the change over distance of the voltages comprising determining the differential voltages of the cells of the fuel cell stack.

37. The method of claim 36, further comprising comparing the differential voltages to a threshold.

38. A method of operating a fuel cell system comprising a plurality of fuel cells connected electrically in series to form a fuel cell stack, the method comprising:
measuring voltages across a semi-conductive measuring strip electrically coupled to the fuel cell stack;
monitoring a change over distance of the voltages present on the measuring strip;
analyzing the change over distance of the voltages present on the measuring strip; and
performing a control action in response to the analysis of the change over distance of the voltages present on the measuring strip.

39. The method of claim 38 wherein measuring voltages across the measuring strip comprises making a plurality of voltage measurements on the measurement strip.

40. The method of claim 39 wherein each of the plurality of voltage measurements is equidistant from each other.

41. The method of claim 39 wherein the number of voltage measurements made is equal to the number of fuel cells in the fuel cell stack.

42. The method of claim 39 wherein the number of voltage measurements made is greater than the number of fuel cells in the fuel cell stack.

43. The method of claim 39 wherein the number of voltage measurements made is less than the number of fuel cells in the fuel cell stack.

44. The method of claim 39 wherein analyzing the change over distance of the voltages comprising determining the differential voltages of the cells of the fuel cell stack.

45. The method of claim 44, further comprising comparing the differential voltages to a threshold.

46. The method of claim 38 wherein performing the control action comprises performing a control action selected from the list of shutting down the fuel cell system, placing the fuel cell system in a reduced power operating state, alerting the operator of the fuel cell system, and modifying the operating conditions of the fuel cell system, and any combination thereof.
